(19) United States
(12) Patent Application Publication
(10) Pub. No.: US 2008/0012973 A1
(43) Pub. Date: Jan. 17, 2008

(54) Image sensors and image sensing methods selecting photocurrent paths according to incident light

(75) Inventors: Jong-Eun Park, Seongnam-si (KR); Yong-Jei Lee, Seongnam-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/806,594

(22) Filed: Jun. 1, 2007

(30) Foreign Application Priority Data
Jul. 14, 2006 (KR) 10-2006-0066500

(51) Int. Cl. H04N 5/335

(52) U.S. Cl. 348/294; 348/E05.091

(57) ABSTRACT

Example embodiments may be directed to CMOS image sensors and image sensing methods selecting a path for photocurrent according to the quantity or amount of incident light. The CMOS image sensor may include a pixel array comprised of a plurality of pixel pairs. A pixel pair may include a first pixel, including a first photo diode, a first pair of transistors, and a first floating diffusion node having a first capacitance. The pixel pair may further include a second pixel, including a second photo diode, a second pair of transistors, and a second floating diffusion node having a second capacitance. A first one of the first pair of transistors may be connected between the first photo diode and the first floating diffusion node. A second one of the first pair of transistors may be connected between the first photo diode and the second floating diffusion node. A first one of the second pair of transistors may be connected between the second photo diode and the second floating diffusion node. A second one of the second pair of transistors may be connected between the second photo diode and a first floating diffusion node of a next pixel pair. The first capacitance of the first floating diffusion node may be greater than the second capacitance of the second floating diffusion node.

### PRIORITY STATEMENT

This application claims priority under 35 U.S.C. §119 to Korean Patent Application No. 10-2006-0066500, filed on Jul. 14, 2006 in the Korean Intellectual Property Office, the entire disclosure of which is incorporated by reference herein.

### BACKGROUND

Example embodiments may relate to image sensors. For example, example embodiments may relate to CMOS image sensors and image sensing methods for selecting a photocurrent path according to the quantity of incident light so as to increase transmission efficiency of an output signal.

### THE CONVENTIONAL ART

Generally, image sensors may be grouped as charge coupled device (CCD) image sensors and CMOS image sensors (CIS). CIS may be more economical than CCD because CIS may use CMOS processes. In addition, CIS may be advantageous in that analog signal processing circuitry and/or digital signal processing circuitry may be integrated in CIS. Furthermore, CIS may allow low-power and low-voltage design, and thus may be acclimated for portable devices such as mobile phones and digital cameras, which may require low power consumption. A pixel array in CIS may include a plurality of pixels arranged in a two-dimensional matrix, where each pixel outputs an image signal in response to light energy.

FIG. 1 illustrates the structure of pixels in a conventional CMOS image sensor. Referring to FIG. 1, each of pixels included in a pixel array includes a photo diode P-1, P-2, P-3, or P-4, a first switch T-1, T-3, T-5, or T-7, a floating diffusion node FD1, FD3, FD5, or FD 7, a reset switch RG, and a second switch SF1, SF3, SF5, or SF7.

The photo-diode P-1 may receive light energy emitted from a luminary, and may generate and accumulates charge. For example, a luminary may be a light source, light emitting device, or an object reflecting light and light energy. The first switch T-1 may transmit the accumulated charges (or photocurrent) to the floating diffusion node FD1 in response to a control signal input through a gate. The floating diffusion node FD1 may receive charge generated by the photo diode P-1 via the first switch T-1, and stores the received charge.

The floating diffusion node FD1 may be configured to a floating diffusion region. Because the floating diffusion node FD1 may have parasitic capacitance, charge generated by the photo diode P-1 may be accumulatively stored in the floating diffusion node FD1. The reset switch RG may be connected between a power supply voltage VDD and the floating diffusion node FD1. The reset switch may reset the floating diffusion node FD1 to the power supply voltage VDD in response to a reset signal RE1.

The second switch SF1 may be connected between the power supply voltage VDD and an output terminal VOUT. The second switch SF1 may perform source-following based on the charge stored in the floating diffusion node FD1. TH second switch SF1 may output a source-followed signal. Accordingly, photoelectric conversion gain, i.e., the magnitude of the source-followed signal with respect to light energy received by the photo diode P-1 may be determined based on the capacitance of the floating diffusion node FD1. In addition, the photoelectric conversion gain may determine a ratio of an output signal of the CMOS image sensor to the quantity of light energy, that is, sensitivity.

For example, if the capacitance of the floating diffusion node FD1 is lower than that of the photo diode P-1, the magnitude of an output signal of the CMOS image sensor may be increased with respect to the small quantity of light energy. In other words, the ratio of an output signal of the CMOS image sensor to the quantity of light energy, i.e., sensitivity is may be increased. However, the charge accumulated at the photo diode P-1 may not be completely transmitted to the floating diffusion node FD1. Accordingly, the charges accumulated at the photo diode P-1 may cause noise to occur during transmission, or during signal processing, thereby decreasing signal-to-noise ratio (SNR). As a result, the picture quality may be degraded.

However, if the capacitance of the floating diffusion node FD1 is higher than that of the photo diode P-1, charges accumulated at the photo diode P-1 may be completely transmitted to the floating diffusion node FD1. Therefore, noise may not occur during transmission or signal processing, and therefore, SNR may be increased. However, the ratio of the output signal of the CMOS image sensor to the low quantity of light energy, i.e., sensitivity may be decreased, and therefore, a blurry image may be output.

FIG. 2 illustrates the structure of pixels in another conventional CMOS image sensor. Referring to FIG. 2, photo diodes P-11 and P-12 may share a first floating diffusion node FD2 and photo diodes P-13 and P-14 may share a second floating diffusion node FD4. Charge accumulated at the photo diode P-11 may always be transmitted to the first floating diffusion node FD2 having constant capacitance. Accordingly, a photoelectric conversion gain, i.e., the magnitude of a source-followed signal with respect to light energy received by the photo diode P-11, may be determined by the capacitance of the first floating diffusion node FD2. The charge accumulated at the photo diode P-11 may always be transmitted to the first floating diffusion node FD2 having constant capacitance even if the photoelectric conversion gain is changed.

For example, even if light energy input to the CMOS image sensor is changed, a path for photocurrent generated at the photo diode P-11 is directed from the photo diode P-11 to the first floating diffusion node FD2, and may always be constant. Accordingly, an output signal of the CMOS image sensor may increase in sensitivity, but may decrease in SNR if the capacitance of the first floating diffusion node FD2 is low with respect to a predetermined quantity of light energy. Conversely, the output signal of the CMOS image sensor may increase in SNR but may decrease in sensitivity if the capacitance of the first floating diffusion node FD2 is high with respect to the predetermined quantity of light energy.

### SUMMARY OF THE INVENTION

Example embodiments may provide CMOS image sensors and an image sensing methods for selecting a path for photocurrent flowing into a floating diffusion node according to the quantity or amount of light incident to the CMOS image sensors, thereby increasing transmission efficiency of an output signal.

According to an example embodiment, a pixel pair may include a first pixel, including a first photo diode, a first pair of transistors, and a first floating diffusion node having a first capacitance. The pixel pair may further include a second pixel, including a second photo diode, a second pair of transistors, and a second floating diffusion node having a second capacitance. A first one of the first pair of transistors may be connected between the first photo diode and the first floating diffusion node. A second one of the first pair of transistors may be connected between the first photo diode and the second floating diffusion node. A first one of the second pair of transistors may be connected between the second photo diode and the second floating diffusion node. A second one of the second pair of transistors may be connected between the second photo diode and a first floating diffusion node of a next pixel pair. The first capacitance of the first floating diffusion node may be greater than the second capacitance of the second floating diffusion node.

In an example embodiments, the pixel pair may further include a first capacitor connected between a gate of the first one of the first pair of transistors and the first floating diffusion node, and a second capacitor connected between a gate of the second one of the second pair of transistors and the first floating diffusion node of the next pixel pair.

In an example embodiment, the first capacitance may include a capacitance of the first capacitor and a parasitic capacitance of the first floating diffusion node.

In an example embodiment, a pixel array may include a plurality of pixel pairs. The pixel array may output a reset signal and a sensing signal. The reset signal and the sensing signal may be based on corresponding selection signals of a plurality of selection signals.

In an example embodiment, an image sensing system may include a pixel array, a row decoder to receive a row address and a plurality of control signals and to generate the plurality of selection signals, a correlated double sampling (CDS) block to receive reset signals and sensing signals output from the pixel array, to perform CDS of the reset signals and the sensing signals, and to output CDS signals, an analog-to-digital converter (ADC) to convert signals output from the CDS block into digital image signals, and an image signal processor (ISP) to output image signals based on the digital image signals and to generate the plurality of control signals based on the image signals.

In at least one example embodiment, the first capacitance includes a parasitic capacitance of the first floating diffusion node and a capacitance of a capacitor.

In an example embodiment, a first floating diffusion region forming the first floating diffusion node is different than a second floating diffusion region forming the second floating diffusion node.

In an example embodiment, a first floating diffusion region forming the first floating diffusion node has a larger area than a second floating diffusion region forming the second floating diffusion node.

In an example embodiment, the pixel pair may further include a first capacitor connected between the first floating diffusion node and a ground wire, and a second capacitor connected between the second floating diffusion node and the ground wire.

In an example embodiment, the first capacitor may have a capacitance greater than a capacitance of the second capacitor.

According to an example embodiment, an image sensing method may include accumulating charge based on incident light energy from a luminary, receiving the charge through a transmission switch, source-following with respect to a power supply voltage based on the charge, and outputting a source-followed signal. The source-following may include source-following through a first floating diffusion node having a first capacitance if an output image of an image sensor is brighter than a predetermined brightness, and source-following through a second floating diffusion node having a second capacitance if an output image of an image sensor is darker than the predetermined brightness.

According to an example embodiment, an image sensor may include a pixel array in which a first pixel and a second pixel are reciprocally arranged. The first pixel may include a first photo diode, a pair of first transistors, and a first floating diffusion node having a first capacitance. The second pixel may include a second photo diode, a pair of second transistors, and a second floating diffusion node having a second capacitance. First one of the pair of first transistors may be connected between the first photo diode and the first floating diffusion node and second one of the pair of first transistors may be connected between the first photo diode and the second floating diffusion node. First one of the pair of second transistors may be connected between the second photo diode and the second floating diffusion node and second one of the pair of second transistors may be connected between the second photo diode and the first floating diffusion node.

The image sensor may further include a first capacitor connected between a gate of the first one of the pair of first transistors and the first floating diffusion node, and a second capacitor connected between a gate of the second one of the pair of second transistors and the first floating diffusion node. The first capacitance may be higher than the second capacitance. A first floating diffusion region forming the first floating diffusion node may be different from a second floating diffusion region forming the second floating diffusion node.

In at least one example embodiment, the image sensor may further include a first capacitor connected between the first floating diffusion node and a ground wire, and a second capacitor connected between the second floating diffusion node and the ground wire. For example, the capacitance of the first capacitor may be higher than the capacitance of the second capacitor.

According to an example embodiment, an image sensing system may include a row decoder receiving a row address and a plurality of control signals and generating a plurality of selection signals. The image sensing system may further include a pixel array in which a first pixel and a second pixel are reciprocally arranged, the pixel array outputting a reset signal and a sensing signal, which are generated by each of the first pixel and the second pixel based on corresponding signals among the plurality of selection signals. The image sensing system may further include a correlated double sampling (CDS) block receiving reset signals and sensing signals output from the pixel array, performing CDS of the reset signals and the sensing signals, and outputting CDS signals. The image sensing system may further include an analog-to-digital converter (ADC) converting signals output from the CDS block into digital image signals, and an image signal processor (ISP) outputting image signals based on the digital image signals and generating the plurality of control signals based on the image signals. The first pixel may include a first photo diode, a pair of first transistors, and a first floating diffusion node having a first capacitance. The second pixel may include a second photo diode, a pair of second transistors, and a second floating diffusion node having a second capacitance. First one of the pair of first transistors is connected between the first photo diode and the first floating diffusion node and second one of the pair of first transistors may be connected between the first photo diode and the second floating diffusion node. First one of the pair of second transistors may be connected between the second photo diode and the second floating diffusion node and second one of the pair of second transistors is connected between the second photo diode and the first floating diffusion node.

The image sensing system may further include a first capacitor connected between a gate of the first one of the pair of first transistors and the first floating diffusion node, and a second capacitor connected between a gate of the second one of the pair of second transistors and the first floating diffusion node. The first capacitance may be higher than the second capacitance. A first floating diffusion region forming the first floating diffusion node may be different from a second floating diffusion region forming the second floating diffusion node.

In at least one example embodiment, the image sensing system may further include a first capacitor connected between the first floating diffusion node and a ground wire, and a second capacitor connected between the second floating diffusion node and the ground wire. For example, the capacitance of the first capacitor may be higher than the capacitance of the second capacitor.

According to an example embodiment, an image sensing method may include generating and accumulating charges based on light energy generated from a luminary, receiving the charges through a transmission switch, and performing source follow with respect to a power supply voltage based on the charges and outputting a source-followed signal. The source following may be performed through a first floating diffusion node having a first capacitance if an output image of an image sensor is brighter than a brightness threshold, and the source following may be performed through a second floating diffusion node having a second capacitance if an output image of an image sensor is darker than the brightness threshold.

### BRIEF DESCRIPTION OF THE DRAWINGS

The above and other features and advantages of the present invention will become more apparent by describing in detail preferred embodiments thereof with reference to the attached drawings in which:

FIG. 1 illustrates the structure of pixels in a conventional CMOS image sensor;

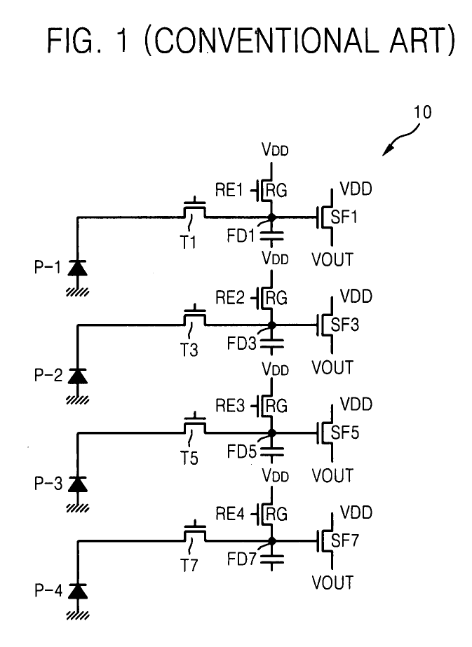

FIG. 2 illustrates the structure of pixels in another conventional CMOS image sensor;

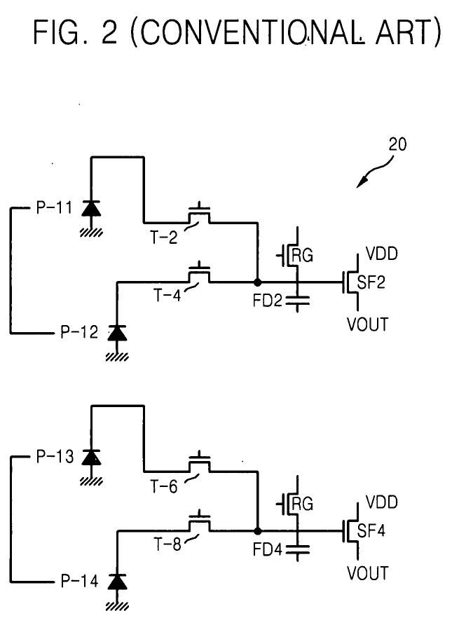

FIG. 3 is a functional block diagram of a CMOS image sensing system including pixels, according to an example embodiment;

FIG. 4A illustrates the structure of pixels and the flow of photocurrent in the CMOS image sensing system illustrated in FIG. 3, according to an example embodiment;

FIG. 4B illustrates the structure of pixels and the flow of photocurrent in the CMOS image sensing system illustrated in FIG. 3, according to an example embodiment;

FIG. 5 illustrates the layout of pixels illustrated in FIG. 4A, according to an example embodiment;

FIG. 6A illustrates the structure of pixels and the flow of photocurrent in the CMOS image sensing system illustrated in FIG. 3, according to an example embodiment;

FIG. 6B illustrates the structure of pixels and the flow of photocurrent in the CMOS image sensing system illustrated in FIG. 3, according to an example embodiment; and

FIG. 7 is a flowchart of an image sensing method, according to an example embodiment.

### DETAILED DESCRIPTION OF EXAMPLE EMBODIMENTS

Detailed illustrative embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

The attached drawings for illustrating example embodiments are referred to in order to gain a sufficient understanding of the example embodiments, the merits thereof, and the objectives accomplished by the implementation of example embodiments. Hereinafter, example embodiments will be described in detail by explaining them with reference to the attached drawings. Like reference numerals in the drawings denote like elements.

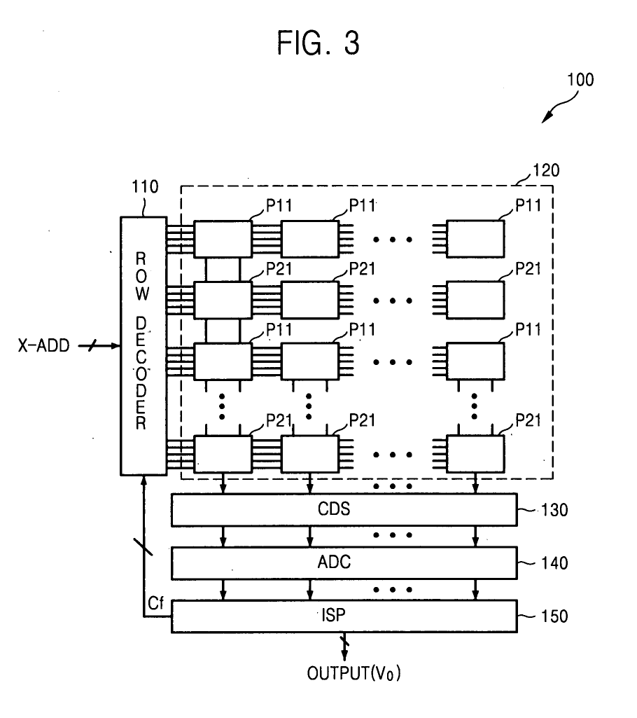

FIG. 3 is a functional block diagram of a CMOS image sensing system 100 including pixels, according to an example embodiment. The CMOS image sensing system 100 may include a row decoder 110, a pixel array 120, a correlated double sampling (CDS) block 130, an analog-to-digital converter (ADC) 140, and an image signal processor (ISP) 150. The CDS block 130 and the ADC 140 may be implemented by a single block, or separately.

The row decoder 110 may receive a row address X-ADD and a plurality of control signals Cf. The row decoder 110 may generate a plurality of selection signals, and may output the plurality of selection signals to the pixel array 120. The pixel array 120 may include a plurality of pixels arranged in a two-dimensional matrix, or array-type formation. For example, a pixel of the plurality of pixels may include P11 or P21. Each of the pixels P11 and P21 of the plurality of pixels may output a reset signal and a sensing signal based on the plurality of selection signals.

The CDS block 130 may receive reset signals and sensing signals from the pixel array 120. Additionally, the CDS block 130 may perform correlated double sampling of the reset signals and the sensing signals, and output correlated sampling signals based on the sampling. The ADC 140 may convert signals output from the CDS block 130 into digital image signals.

The ISP 150 may output image signals V₀ based on digital image signals output from the ADC 140. The ISP may, additionally, generate the plurality of the control signals Cf based on the image signals V₀.

A photocurrent path for each of the pixels P11 and P21 may be selected based on the plurality of the control signals Cf, according to the quantity of light energy input to the CMOS image sensing system 100. Photocurrent path selection will be described in more detail later.

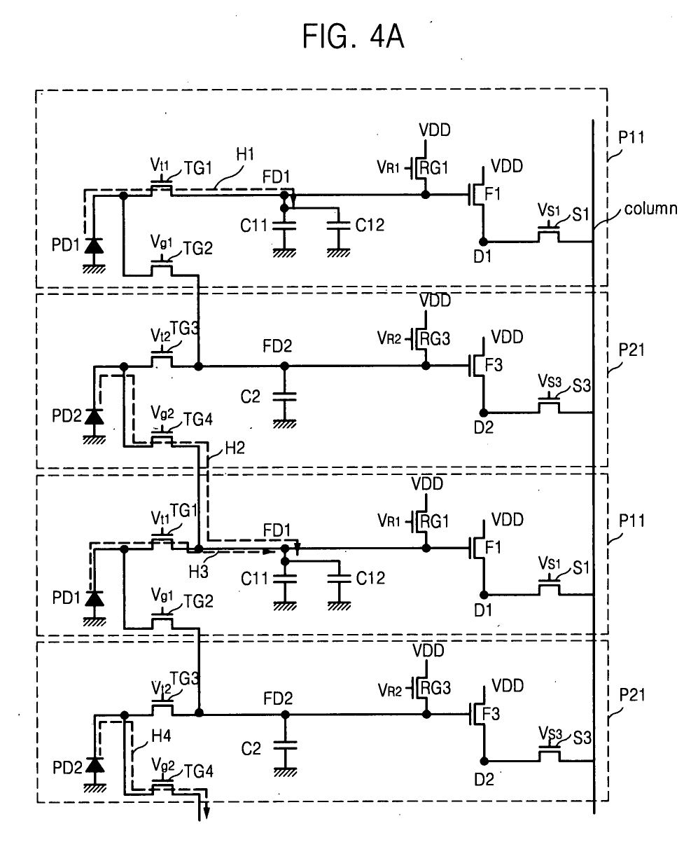

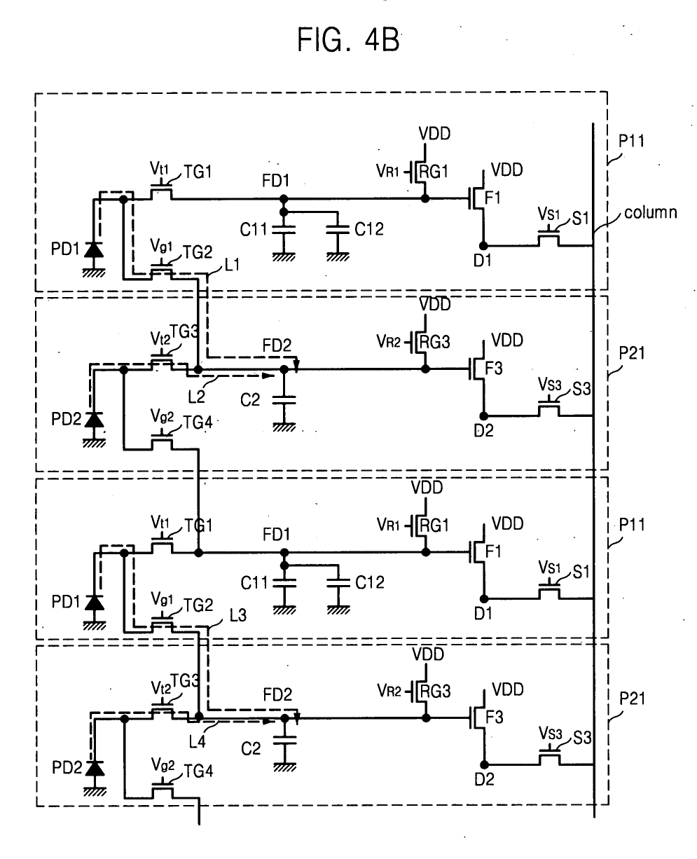

FIGS. 4A and 4B illustrate the structures of pixels and flow directions of photocurrent in the CMOS image sensing system 100 illustrated in FIG. 3, respectively, according to an example embodiment. FIG. 4A shows the flow of photocurrent if an output image of the CMOS image sensing system 100 is brighter than a predetermined or desired brightness (e.g., a default brightness value or a brightness threshold). FIG. 4B shows the flow of photocurrent if an output image of the CMOS image sensing system 100 is darker than the predetermined or desired brightness.

Referring to FIG. 3 through 4B, the pixel array 120 in the CMOS image sensing system 100 may include a plurality of first pixels P11 and a plurality of second pixels P21. The first pixels P11 and the second pixels P21 may be arranged reciprocally, i.e., the arrangement of pixels in the CMOS image sensing system 100 may alternate from P11 to P21, and vice versa. For example, a pixel P11 and a pixel P21 may form a pixel pair.

Each of the first pixels P11 may include a first photo diode PD1, a first transmission transistor TG1, a second transmission transistor TG2, a first floating diffusion node FD1, a first reset transistor RG1, a first amplification transistor F1, and a first selection transistor S1.

The first photo diode PD1 may accumulate charge generated from absorbing light energy reflected by an object. The first photo diode PD1 may be implemented by a photo diode, a photo transistor, a photo gate, a pinned photo diode (PPD), any combination thereof, or any suitable photo-sensitive device.

The row decoder 110 may output the plurality of selection signals including a first control signal Vₜ₁, a second control signal V_{g1}, a reset signal V_{R1}, and a selection signal V_{S1}. The first transmission transistor TG1 may transmit charge or photocurrent accumulated at the first photo diode PD1 to the first floating diffusion node FD1 in response to the first control signal Vₜ₁.

The second transmission transistor TG2 may transmit charge or photocurrent accumulated at the first photo diode PD1 to a second pixel P21 in response to the second control signal V_{g1}. The accumulated charge or photocurrent may be transmitted to a floating diffusion node included in the second pixel P21. For example, if the first control signal Vₜ₁ is activated, the second control signal V_{g1} may be deactivated. If the first control signal Vₜ₁ is deactivated, the second control signal V_{g1} may be activated.

The first floating diffusion node FD1 may include a floating diffusion region. The first floating diffusion node FD1 may receive accumulated charges from the first photo diode PD1. The first floating diffusion node FD1 may have a parasitic capacitance C11 and thus, may accumulatively store charge from the first photo diode PD1. A capacitor C12 having a predetermined or desired capacitance may be connected to the first floating diffusion node FD1. For example, the capacitor C12 may be connected in parallel to the parasitic capacitance C11.

The first reset transistor RG1 may be connected between a first power supply voltage VDD and the first floating diffusion node FD1. The first reset transistor RG1 may reset, i.e., pull up the first floating diffusion node FD1 to a VDD level in response to the reset signal VR1.

The first amplification transistor F1 may be connected between the first power supply voltage VDD and a first node D1. The first amplification transistor F1 may source-follow on the first node D1 with the first power supply voltage VDD according to the amount of charge accumulated at the first floating diffusion node FD1. The first selection transistor S1 may output a source-followed signal output from the first amplification transistor F1 to a column in response to the selection signal V_{S1}.

Each of the second pixels P21 may include a second photo diode PD2, a third transmission transistor TG3, a fourth transmission transistor TG4, a second floating diffusion node FD2, a second reset transistor RG3, a second amplification transistor F3, and a second selection transistor S3.

The second photo diode PD2 may accumulate charge generated from absorbing light energy reflected by an object. The second photo diode PD2 may be implemented by a photo diode, a photo transistor, a photo gate, a pinned photo diode (PPD), any combination thereof, or any suitable photo-sensitive device.

The third transmission transistor TG3 may transmit charge or photocurrent accumulated at the second photo diode PD2 to the second floating diffusion node FD2 in response to a control signal Vₜ₂ output from the row decoder 110. The row decoder 110 may output the plurality of selection signals including a third control signal Vₜ₂, a fourth control signal V_{g2}, a reset signal V_{g2}, and a selection signal V_{S3}.

The fourth transmission transistor TG4 may transmit charge or photocurrent accumulated at the second photo diode PD2 a first pixel P11 in response to the fourth control signal V_{g2}. The accumulated charge or photocurrent may be transmitted to a floating diffusion node included in the first pixel P11. The second floating diffusion node FD2 may be configured to a floating diffusion region and may receive charge accumulated at the first photo diode PD1 via the second transmission transistor TG2. Alternatively, the second floating diffusion node FD2 may receives charge accumulated at the second photo diode PD2 via the third transmission transistor TG3. The second floating diffusion node FD2 may have a parasitic capacitance C2 and thus, may accumulatively store charge from the first photo diode PD1 or the second photo diode PD2. The capacitance of the second floating diffusion node FD2 may be lower than that of the first floating diffusion node FD1.

The second reset transistor RG3 may be connected between the first power supply voltage VDD and the second floating diffusion node FD2. The second reset transistor may reset the second floating diffusion node FD2 in response to the reset signal V_{R2}.

The second amplification transistor F3 may be connected between the first power supply voltage VDD and a second node D2. The second amplification transistor may source-follow the second node D2 with the first power supply voltage VDD according to the amount of charge accumulated at the second floating diffusion node FD2. The second selection transistor S3 may output a source-followed signal output from the second amplification transistor F3 to a column in response to the selection signal V_{S3}. Therefore, the pixels may be grouped as pairs of first pixels P11 and second pixels P21, including a first floating diffusion node FD1 in the first pixel P11, and a second floating diffusion node FD2 in the second pixel P21.

Referring to FIG. 4A, dotted lines H1, H2, H3, and H4 may indicate the flow of photocurrent if an output image of the CMOS image sensing system 100 illustrated in FIG. 3 is brighter than the predetermined or desired brightness. If the output image of the CMOS image sensing system 100 is generated brighter than the predetermined or desired brightness based on signals output from the ADC 140 (illustrated in FIG. 3), the SIP 150 may generate the plurality of control signals Cf to control photocharge (or photocurrent) generated by a corresponding photo diode for accumulation at a corresponding first floating diffusion node FD1. For example, the first transmission transistor TG1 and the fourth transmission transistor TG4 are turned on in response to the control signals Vₜ₁ and V_{g2}, respectively, and the second transmission transistor TG2 and the third transmission transistor TG3 are turned off in response to the control signals V_{g1} and Vₜ₂, respectively. Therefore, photocharge generated by each of the first and second photo diodes PD1 and PD2 may be accumulated at a corresponding first floating diffusion node FD1.

Referring to FIG. 4B, dotted lines L1, L2, L3, and L4 may indicate the flow of photocurrent if an output image of the CMOS image sensing system 100 (illustrated in FIG. 3) is darker than the predetermined or desired brightness. If the output image of the CMOS image sensing system 100 is darker than the predetermined or desired brightness, the SIP 150 may generate the plurality of control signals Cf to control photocharge generated by a corresponding photo diode for accumulation at a corresponding second floating diffusion node FD2. For example, the first transmission transistor TG1 and the fourth transmission transistor TG4 are turned off in response to the control signals Vₜ₁ and V_{g2}, respectively, and the second transmission transistor TG2 and the third transmission transistor TG3 are turned on in response to the control signals V_{g1} and Vₜ₂, respectively. Therefore, photocharge generated by each of the first and second photo diodes PD1 and PD2 may be accumulated at a corresponding second floating diffusion node FD2.

According to an example embodiment, the CMOS image sensing system 100 may change a path for photocurrent transmitted to a floating diffusion node according to whether an output image is brighter or darker than the predetermined or desired brightness. For example, according to the quantity of light energy input by the CMOS image sensing system 100.

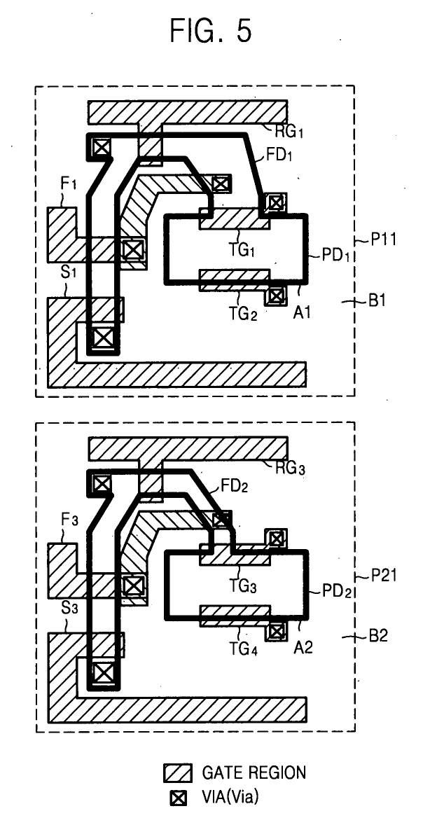

FIG. 5 illustrates the layout of the pixels P11 and P21 illustrated in FIG. 4A, according to an example embodiment. Referring to FIG. 3 through 5, in the layout of the pixels P11 and P21, which may be unit pixels constructing the pixel array 120, regions A1 and A2 defined by a bold solid line are active regions. Outside regions B1 and B2 of the active regions A1 and A2 are isolation regions.

Gates of the respective transmission transistors TG1 through TG4, gates of the reset transistors RG1 and RG3, gates of the amplification transistors F1 and F3, and gates of the selection transistors S1 and S3, may be disposed to cross over the corresponding active regions A1 and A2. As is illustrated in FIG. 5, the area of a floating diffusion region forming the first floating diffusion node FD1 may be larger than that of a floating diffusion region forming the second floating diffusion node FD2.

The floating diffusion region forming the first floating diffusion node FD1, and the floating diffusion region forming the second floating diffusion node FD2, may each have a parasitic capacitance proportional to their area. Accordingly, the capacitance of the first floating diffusion node FD1 may higher than that of the second floating diffusion node FD2.

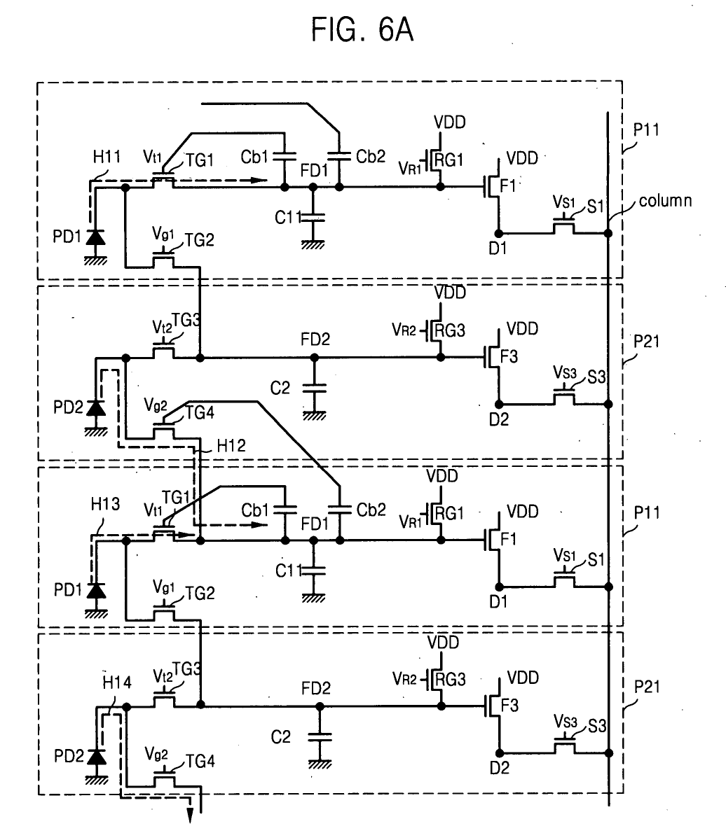

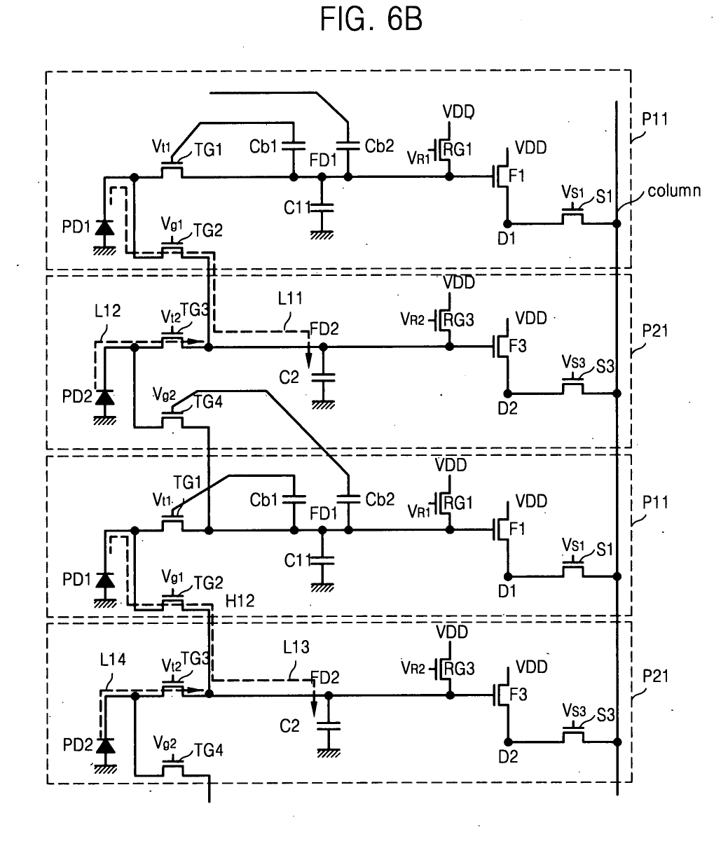

FIGS. 6A and 6B illustrate the structures of pixels and the flow of photocurrent in the CMOS image sensing system 100 illustrated in FIG. 3, according to an example embodiment. FIG. 6A shows the flow of photocurrent if an output image of the CMOS image sensing system 100 is brighter than a predetermined or desired brightness. FIG. 6B shows the flow of photocurrent if an output image of the CMOS image sensing system 100 is darker than the predetermined or desired brightness.

Referring to FIGS. 3 and 6A, the pixel array 120 in the CMOS image sensing system 100 may include a plurality of the first pixels P11 and a plurality of the second pixels P21. Each first pixel P11 illustrated in FIG. 6A may additionally include first and second boosting capacitors Cb1 and Cb2 as compared to each first pixel P11 illustrated in FIG. 4A.

The first boosting capacitor Cb1 may be connected between the gate of the first transmission transistor TG1 and the first floating diffusion node FD1. The first boosting capacitor Cb1 may be charged by the first control signal Vₜ₁ and may pump charge in response to photocurrent generated by the first photo diode PD1 and the second photo diode PD2. Accordingly, the capacitance of the first floating diffusion node FD1 may increase proportional to the pumped charge. The second boosting capacitor Cb2 may be connected between the gate of the fourth transmission transistor TG4 and the first floating diffusion node FD1. The second boosting capacitor Cb2 may be charged by the fourth control signal V_{g2} and may pump charge in response to photocurrent generated by the first photo diode PD1 and the second photo diode PD2. Accordingly, the capacitance of the first floating diffusion node FD1 may increase proportional to the pumped charge. Therefore, the capacitance of the first floating diffusion node FD1 may become higher than that of the second floating diffusion node FD2.

Referring to FIG. 6A, dotted lines H11, H12, H13, and H14 may indicate the flow of photocurrent if an output image of the CMOS image sensing system 100 illustrated in FIG. 3 is brighter than the predetermined or desired brightness. If the output image of the CMOS image sensing system 100 is brighter than the predetermined or desired brightness, the SIP 150 illustrated in FIG. 3 may generate the plurality of control signals Cf to control photocharge for accumulation at first floating diffusion nodes FD1. For example, FIG. 6A illustrates photocurrent paths H11, H12, H13, and H14 if the first transmission transistor TG1 and the fourth transmission transistor TG4 are turned on, and the second transmission transistor TG2 and the third transmission transistor TG3 are turned off. Therefore, in FIG. 6A, photocurrent generated by the first and second photo diodes PD1 and PD2 may be accumulated at the first floating diffusion nodes FD1.

Referring to FIG. 6B, dotted lines L11, L12, L13, and L14 may indicate the flow of photocurrent if an output image of the CMOS image sensing system 100 illustrated in FIG. 3 is darker than the predetermined or desired brightness. If the output image of the CMOS image sensing system 100 is darker than the predetermined or desired brightness, the SIP 150 illustrated in FIG. 3 may generate the plurality of control signals Cf to control photocharge for accumulation at second floating diffusion nodes FD2. For example, FIG. 6B illustrates photocurrent paths L11, L12, L13, and L14 if the first transmission transistor TG1 and the fourth transmission transistor TG4 are turned off, and the second transmission transistor TG2 and the third transmission transistor TG3 are turned on. Therefore, in FIG. 6B, photocharge generated by the first and second photo diodes PD1 and PD2 may be accumulated at the second floating diffusion nodes FD2.

Accordingly, the CMOS image sensing system 100 may select a path for photocurrent transmitted to a floating diffusion node according to whether an output image is brighter or darker than the predetermined or desired brightness. For example, according to the quantity of light energy input by CMOS image sensing system 100.

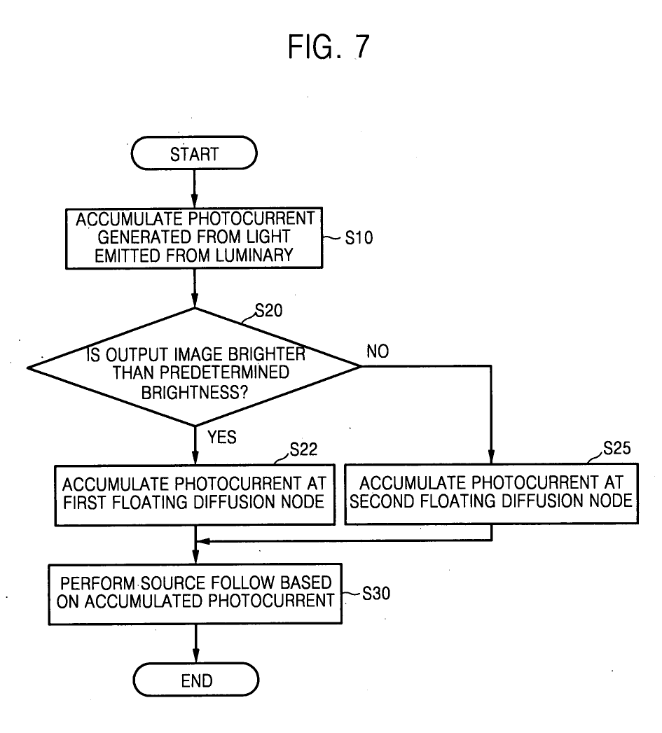

FIG. 7 is a flowchart of an image sensing method, according to an example embodiment. Referring to FIGS. 3, 4A, and 7, in operation S10, each of the photo diodes PD1 and PD2 may accumulate charge generated from absorbing light energy reflected by an object.

In operation S20, the ISP 150 may determine whether an output image of the CMOS image sensing system 100 is brighter than a predetermined or desired brightness. If the output image of the CMOS image sensing system 100 is brighter than the predetermined or desired brightness, the charge accumulated at each of the photo diodes PD1 and PD2 may be accumulated at a first floating diffusion node FD1 in operation S22.

However, if the output image of the CMOS image sensing system 100 is darker than the predetermined or desired brightness, the charge accumulated at each of the photo diodes PD1 and PD2 may be accumulated at a second floating diffusion node FD2 in operation S25.

In operation S30, each of the first and second amplification transistors F1 and F3 performs source-follow on the corresponding node D1 or D2, with the first power supply voltage VDD according to the amount of charge accumulated at the corresponding floating diffusion node FD1 or FD2.

As described above, according to example embodiments, two floating diffusion nodes are provided for a single photo diode such that a path for photocurrent flowing to a floating diffusion node may be selected according to light incident on a CMOS image sensor. Therefore, transmission efficiency of an output signal of the CMOS image sensor may be increased.

While example embodiments been particularly shown and described with reference to the figures, it will be understood by those of ordinary skill in the art that various changes in form and details may be made therein without departing from the spirit and scope of the present invention as defined by the following claims.

What is claimed is:

1. A pixel pair comprising:
a first pixel, including a first photo diode, a first pair of transistors, and a first floating diffusion node having a first capacitance;
a second pixel, including a second photo diode, a second pair of transistors, and a second floating diffusion node having a second capacitance; wherein,
a first one of the first pair of transistors is connected between the first photo diode and the first floating diffusion node;
a second one of the first pair of transistors is connected between the first photo diode and the second floating diffusion node;
a first one of the second pair of transistors is connected between the second photo diode and the second floating diffusion node; and
a second one of the second pair of transistors is connected between the second photo diode and a first floating diffusion node of a next pixel pair; and
the first capacitance is greater than the second capacitance.

2. The pixel pair of claim 1, further comprising:
a first capacitor connected between a gate of the first one of the first pair of transistors and the first floating diffusion node; and
a second capacitor connected between a gate of the second one of the second pair of transistors and the first floating diffusion node of the next pixel pair.

3. The pixel pair of claim 2, wherein the first capacitance includes a capacitance of the first capacitor and a parasitic capacitance of the first floating diffusion node.

4. A pixel array comprising:
a plurality of pixel pairs as defined in claim 1, wherein:
the pixel array outputs a reset signal and a sensing signal;
the reset signal and the sensing signal are based on corresponding selection signals of a plurality of selection signals.

5. An image sensing system comprising:
the pixel array as defined in claim 4;
a row decoder to receive a row address and a plurality of control signals and to generate the plurality of selection signals;
a correlated double sampling (CDS) block to receive reset signals and sensing signals output from the pixel array, to perform CDS of the reset signals and the sensing signals, and to output CDS signals;
an analog-to-digital converter (ADC) to convert signals output from the CDS block into digital image signals; and
an image signal processor (ISP) to output image signals based on the digital image signals and to generate the plurality of control signals based on the image signals.

6. The pixel pair of claim 1, wherein the first capacitance includes a parasitic capacitance of the first floating diffusion node and a capacitance of a capacitor.

7. A pixel array comprising:
a plurality of pixel pairs as defined in claim 6, wherein:
the pixel array outputs a reset signal and a sensing signal;
the reset signal and the sensing signal are based on corresponding selection signals of a plurality of selection signals.

8. An image sensing system comprising:
the pixel array as defined in claim 7;
a row decoder to receive a row address and a plurality of control signals and to generate the plurality of selection signals;
a correlated double sampling (CDS) block to receive reset signals and sensing signals output from the pixel array, to perform CDS of the reset signals and the sensing signals, and to output CDS signals;
an analog-to-digital converter (ADC) to convert signals output from the CDS block into digital image signals; and
an image signal processor (ISP) to output image signals based on the digital image signals and to generate the plurality of control signals based on the image signals.

9. The pixel pair of claim 1, wherein a first floating diffusion region forming the first floating diffusion node is different than a second floating diffusion region forming the second floating diffusion node.

10. The pixel pair of claim 1, wherein a first floating diffusion region forming the first floating diffusion node has a larger area than a second floating diffusion region forming the second floating diffusion node.

11. The pixel pair of claim 1, further comprising:
a first capacitor connected between the first floating diffusion node and a ground wire; and
a second capacitor connected between the second floating diffusion node and the ground wire.

12. The pixel pair of claim 11, wherein the first capacitor has a capacitance greater than a capacitance of the second capacitor.

13. A pixel array comprising:
a plurality of pixel pairs as defined in claim 11, wherein:
the pixel array outputs a reset signal and a sensing signal;
the reset signal and the sensing signal are based on corresponding selection signals of a plurality of selection signals.

14. An image sensing system comprising:
the pixel array as defined in claim 13;
a row decoder to receive a row address and a plurality of control signals and to generate the plurality of selection signals;
a correlated double sampling (CDS) block to receive reset signals and sensing signals output from the pixel array, to perform CDS of the reset signals and the sensing signals, and to output CDS signals;
an analog-to-digital converter (ADC) to convert signals output from the CDS block into digital image signals; and
an image signal processor (ISP) to output image signals based on the digital image signals and to generate the plurality of control signals based on the image signals.

15. A pixel array including a plurality of pixel pairs as defined in claim 1, wherein:
the pixel array outputs a reset signal and a sensing signal;
the reset signal and the sensing signal are based on corresponding selection signals of a plurality of selection signals.

16. An image sensing system comprising:
the pixel array as defined in claim 15;
a row decoder to receive a row address and a plurality of control signals and to generate the plurality of selection signals;
a correlated double sampling (CDS) block to receive reset signals and sensing signals output from the pixel array, to perform CDS of the reset signals and the sensing signals, and to output CDS signals;
an analog-to-digital converter (ADC) to convert signals output from the CDS block into digital image signals; and
an image signal processor (ISP) to output image signals based on the digital image signals and to generate the plurality of control signals based on the image signals.

17. An image sensing method, comprising:
accumulating charge based on incident light energy from a luminary;
receiving the charge through a transmission switch;
source-following with respect to a power supply voltage based on the charge; and
outputting a source-followed signal;
wherein source-following includes source-following through a first floating diffusion node having a first capacitance if an output image of an image sensor is brighter than a brightness threshold, and source-following through a second floating diffusion node having a second capacitance if an output image of an image sensor is darker than the brightness threshold.

18. The method of claim 17, wherein the first capacitance is greater than the second capacitance.
